(19) United States
(12) Patent Application Publication
(10) Pub. No.: US 2020/0091087 A1
(43) Pub. Date: Mar. 19, 2020

(54) SEMICONDUCTOR MEMORY AND SEMICONDUCTOR MEMORY MANUFACTURING METHOD

(71) Applicant: Toshiba Memory Corporation, Tokyo (JP)

(72) Inventors: Shinji YAMASHITA, Yokohama Kanagawa (JP); Soichiro IBARAKI, Kawasaki Kanagawa (JP)

(21) Appl. No.: 16/288,066

(22) Filed: Feb. 27, 2019

(30) Foreign Application Priority Data
Sep. 18, 2018 (JP) 2018-173753

(51) Int. Cl. H01L 23/556; H01L 27/11; H01L 27/115; H01L 23/00

(52) U.S. Cl. CPC H01L 23/556; H01L 24/32; H01L 27/115; H01L 27/11

(57) ABSTRACT

A semiconductor memory includes a substrate having a first surface, a memory device mounted on the first surface, a controller mounted on the first surface, and a shielding layer between the first surface and at least a part of the controller, the shielding layer having a thickness that is large enough to block most of the alpha radiation from the substrate from reaching the part of the controller.

### CROSS-REFERENCE TO RELATED APPLICATION

This application is based upon and claims the benefit of priority from Japanese Patent Application No. 2018-173753, filed Sep. 18, 2018, the entire contents of which are incorporated herein by reference.

### FIELD

Embodiments described herein relate generally to a semiconductor memory and a semiconductor memory manufacturing method.

### BACKGROUND

Conventionally, a semiconductor memory having a plurality of memory devices integrated with a controller that controls data to be read from the memory devices and data to be written to the memory devices, is known.

### DESCRIPTION OF THE DRAWINGS

FIG. 1 is a schematic cross-sectional view of a semiconductor memory according to a first embodiment.

FIG. 2 is a schematic cross-sectional view of a substrate in the semiconductor memory according to the first embodiment.

FIG. 3 is a graph that represents a correlation between energy of alpha particles and a range of the alpha particles in different materials.

FIG. 4 is a cross-sectional view illustrating one step of a manufacturing method for the semiconductor memory according to the first embodiment.

FIG. 5 is a cross-sectional view illustrating another step in the manufacturing method for the semiconductor memory according to the first embodiment.

FIG. 6 is a schematic cross-sectional view of a semiconductor memory according to a second embodiment.

FIG. 7 is a cross-sectional view illustrating one step of a manufacturing method for the semiconductor memory according to the second embodiment.

FIG. 8 is a cross-sectional view illustrates another step in the manufacturing method for the semiconductor memory according to the second embodiment.

FIG. 9 is a schematic cross-sectional view of a semiconductor memory according to a third embodiment.

FIG. 10 is a cross-sectional view illustrating one step of a manufacturing method for the semiconductor memory according to the third embodiment.

FIG. 11 is a schematic cross-sectional view of a semiconductor memory according to a fourth embodiment.

FIG. 12 is a cross-sectional view illustrating one step of a manufacturing method for the semiconductor memory according to the fourth embodiment.

FIG. 13 is a schematic plan view of part of a semiconductor memory according to a modification of the embodiments.

### DETAILED DESCRIPTION

In general, according to one embodiment, a semiconductor memory includes a substrate having a first surface, a memory device mounted on the first surface, a controller mounted on the first surface, and a shielding layer between the first surface and at least a part of the controller, the shielding layer having a thickness that is large enough to block most of the alpha radiation from the substrate from reaching the part of the controller.

Embodiments of a semiconductor memory are described hereinafter. Configurations and methods (and technical features) of embodiments illustrated below and operations and results (and effects) produced by the configurations and the methods are given as examples. Furthermore, although a plurality of embodiments are illustrated below, similar configurations thereto are within the scope of this disclosure. In each embodiment, therefore, similar operations and effects based on the similar configuration are obtained. It is noted that similar elements are denoted by common reference symbols and repetitive description thereof is omitted.

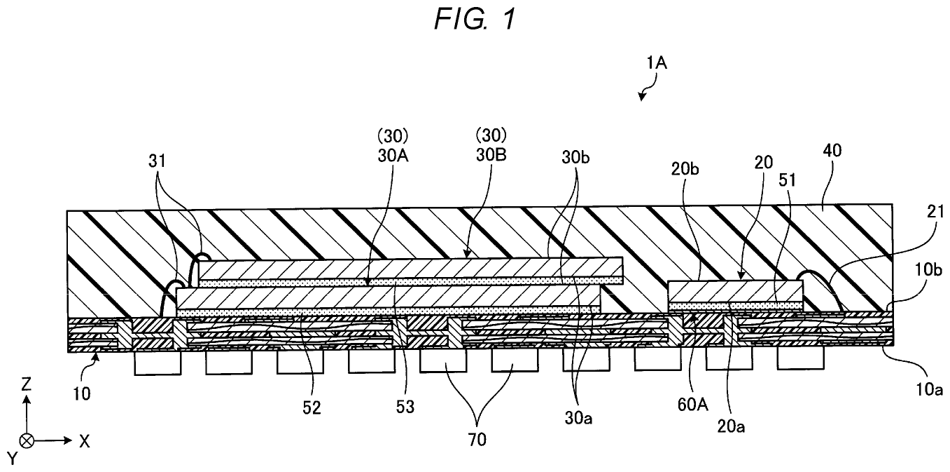

Moreover, arrows indicating directions are illustrated in each drawing for the sake of convenience. Directions X, Y, and Z are orthogonal to one another. The directions X and Y are directions parallel to a bottom surface 10a and a top surface 10b of a substrate 10, and the direction Z is a normal direction relative to the bottom surface 10a and the top surface 10b of the substrate 10; in other words, the direction Z is a thickness direction of the substrate 10. Furthermore, a direction in which the top surface 10b of the substrate 10 is oriented, that is, an upward direction in FIG. 1 may be simply referred to as “upward”, and a direction in which the bottom surface 10a of the substrate 10 is oriented, that is, a downward direction in FIG. 1 may be simply referred to as “downward” hereinafter, for the sake of convenience. Moreover, the direction X is a rightward direction in each drawing.

### First Embodiment

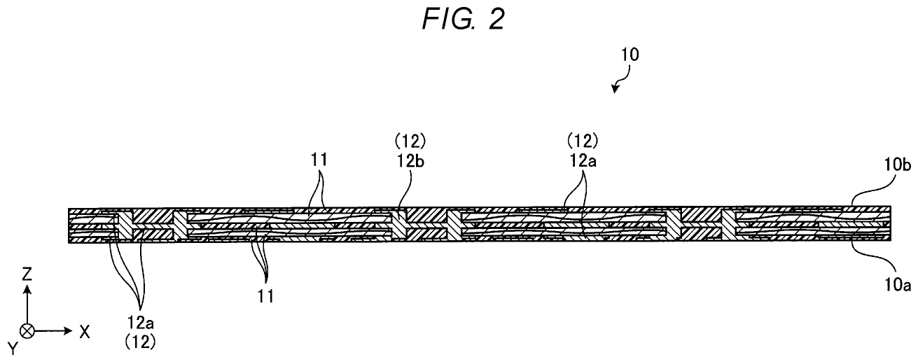

FIG. 1 is a cross-section of a semiconductor memory 1A taken in the XZ plane and viewed along the Y direction. FIG. 2 is a cross-section of the substrate 10 taken in the XZ plane and viewed along the Y direction.

As shown in FIG. 1, the semiconductor memory 1A includes the substrate 10, a controller 20, a memory devices 30, and a cover layer 40.

As shown in FIG. 2, the substrate 10 is a circuit board, which is, for example, a printed circuit board. The substrate 10 has a flattened plate-like shape and has the bottom surface 10a and the top surface 10b parallel to each other. The bottom surface 10a and the top surface 10b both intersect the Z direction and are generally orthogonal to the direction Z. The substrate 10 is, for example, a multilayer substrate or a buildup substrate. Alternatively, the substrate 10 is, for example, an organic substrate such as a glass epoxy substrate.

As shown in FIG. 2, the substrate 10 has insulating layers 11 and conductors 12. The insulating layers 11 are formed from an insulating material such as glass or epoxy resin. The conductors 12 are formed from a high conductivity metallic material such as copper. The conductors 12 have interconnection patterns 12a (referred to herein as conductor layers) and through vias 12b. The through vias 12b are, for example, through-holes or vias. The insulating layers 11 are an example of a first layer.

A copper thin film 60A is partially provided on the top surface 10b of the substrate 10. The copper thin film 60A is provided on a resist on the top surface 10b, and not electrically connected to the conductors 12 of the substrate 10; in other words, the copper thin film 60A is insulated from the conductors 12 of the substrate 10 by the resist. The copper thin film 60A is external to the substrate 10.

The controller 20 shown in FIG. 1 controls data to be read from the memory devices 30 and data to be written to the memory devices 30. The controller 20 may execute other control than the read and write control. Furthermore, the controller 20 has a flattened rectangular parallelepiped shape and has a bottom surface 20a and a top surface 20b parallel to each other. The bottom surface 20a and the top surface 20b both intersect the Z direction and are generally orthogonal to the direction Z.

The controller 20 is mounted on the top surface 10b of the substrate 10. The controller 20 is adhesively bonded onto the copper thin film 60A via, for example, a die attach film 51 (DAF 51). That is, the DAF 51 lies between the copper thin film 60A and the bottom surface 20a and adhesively bonds the copper thin film 60A to the bottom surface 20a. It is noted that the copper thin film 60A may lie between the top surface 10b of the substrate 10 and at least part of the bottom surface 20a of the controller 20. That is, the copper thin film 60A may be narrower than the bottom surface 20a of the controller 20. In such a case, the DAF 51 lies between the copper thin film 60A and the bottom surface 20a and between the top surface 10b of the substrate 10 and the bottom surface 20a, and adhesively bonds the copper thin film 60A and the top surface 10b to the bottom surface 20a. The DAF 51 may be also referred to as “adhesive layer”.

The DAF 51 is provided on a bottom surface of a wafer (not shown) integrally having regions of a plurality of controllers 20 in a manufacturing process of the controllers 20. The DAF 51 is provided on the bottom surface 20a of each controller 20 by cutting the wafer and separating the plurality of controllers 20 by dicing. In addition, the controller 20 is electrically connected to a conductor section (not shown), for example, an interconnection pattern, of the substrate 10 via a bonding wire 21.

A tiny amount of a component contained in glass or the like of the insulating layers 11 in the substrate 10 configured as the organic substrate often emits alpha radiation. The alpha radiation often causes occurrence of a data error (referred to as soft error) in a RAM such as a static random access memory (SRAM) incorporated in the controller 20. In the present embodiment, therefore, the copper thin film 60A that inhibits travel of the alpha radiation is provided between the top surface 10b of the substrate 10 and the controller 20. The copper thin film 60A is an example of a shielding layer.

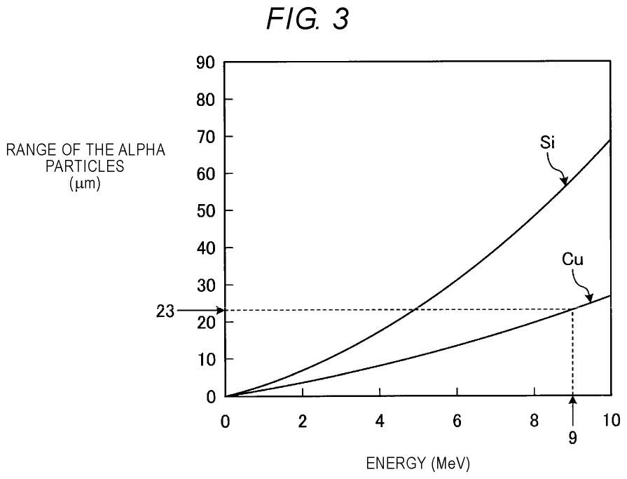

FIG. 3 is a graph that represents a correlation between energy of alpha particles and a range (traveling distance) of the alpha particles in materials (Si and Cu). It is understood from the graph of FIG. 3 that the range of the alpha radiation in copper (Cu) is shorter than that of the alpha radiation in silicon (Si). This signifies that it is difficult for silicon to inhibit the alpha radiation from traveling without making silicon relatively thick and that it is easy for copper to inhibit the alpha radiation from traveling even if copper is relatively thin. It is also confirmed that the energy of the alpha radiation emitted from a radioactive substance (typically, 235U, 238U, 232Th, or the like) contained in the organic substrate is in a range of 4 to 9 [MeV], that is, 9 [MeV] at most. It is clear from FIG. 3 that the range of the alpha radiation at 9 [MeV] in the copper material is 23 [μm]. In view of the foregoing, it is possible to block most of the alpha radiation emitted from the substrate 10 if a thickness of the copper thin film 60A is equal to or greater than 23 [μm].

The memory devices 30 shown in FIG. 1 are nonvolatile memory devices, which are, for example, NAND-type flash memory devices. Each of the memory devices 30 has a flattened rectangular parallelepiped shape and has a bottom surface 30a and a top surface 30b parallel to each other. The bottom surface 30a and the top surface 30b both intersect the Z direction and are, in the present embodiment, generally orthogonal to the Z direction.

The two memory devices 30A and 30B (30) are mounted on the top surface 10b of the substrate 10. The two memory devices 30A and 30B are stacked in the Z direction. It is noted that three or more memory devices 30 may be stacked, or the memory devices 30 may be provided at a plurality of positions on the top surface 10b, or a plurality of memory devices 30 may be stacked at a plurality of positions on the top surface 10b in the semiconductor memory 1A. Furthermore, one or more memory devices 30 may cover the controller 20.

The memory device 30A closer to the substrate 10 out of the two memory devices 30 is adhesively bonded onto the top surface 10b via a DAF 52. The DAF 52 lies between the top surface 10b and the bottom surface 30a of the memory device 30A and adhesively bonds the top surface 10b to the bottom surface 30a. The other memory device 30B farther from the substrate 10 out of the two memory devices 30 is adhesively bonded onto the top surface 30b of the memory device 30A via a DAF 53. The DAF 53 lies between the top surface 30b of the memory device 30A and the bottom surface 30a of the memory device 30B and adhesively bonds the top surface 30b to the bottom surface 30a. The DAFs 52 and 53 may be also referred to as “adhesive layers”.

The DAFs 52 and 53 are provided on a bottom surface of a wafer (not shown) having regions of a plurality of memory devices 30 formed in a manufacturing process of the memory devices 30. The DAFs 52 and 53 are provided on the bottom surfaces 30a of the respective memory devices 30 by cutting the wafer to separate the plurality of memory devices 30 by dicing. Furthermore, each of the memory devices 30 is electrically connected to a conductor section (not shown) which is, for example, an interconnection pattern on the substrate 10 via a bonding wire 31.

The cover layer 40 is provided on the top surface 10b of the substrate 10 and covers the substrate 10. The controller 20 and the two memory devices 30 are packaged in the cover layer 40 and the substrate 10. The cover layer 40 is formed from an insulating synthetic resin material. The synthetic resin material is, for example, epoxy resin into which an organic substance such as silicon dioxide is mixed. The cover layer 40 may be also referred to as “sealing resin”.

A plurality of external electrodes 70 are provided on the bottom surface 10a of the substrate 10. The external electrodes 70 electrically connect the conductors 12 in the semiconductor memory 1A to external conductors (for example, conductors of a substrate on which the semiconductor memory 1A is mounted, not shown). It is noted that the semiconductor memory 1A is a thin semiconductor memory 1A, a thickness of which, except for the external electrodes 70, is equal to or smaller than approximately 1.2 mm (in the Z direction).

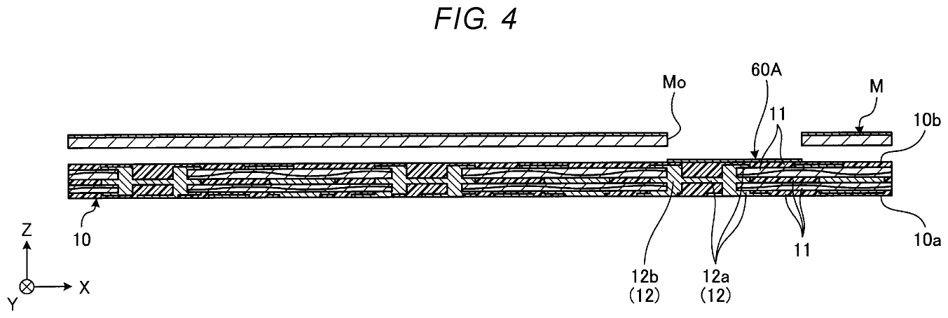

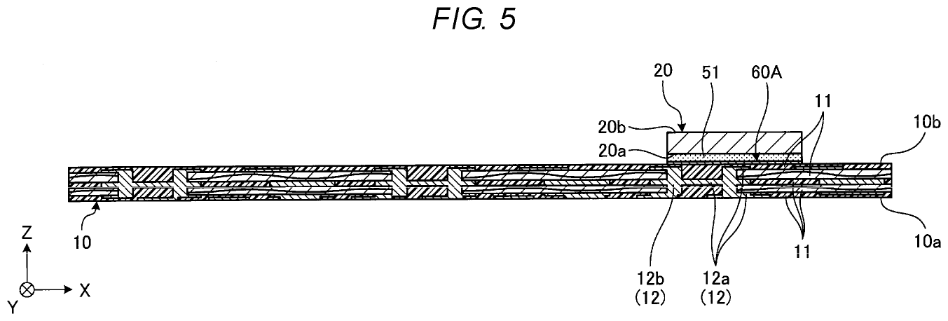

FIGS. 4 and 5 are cross-sectional views illustrating two steps of a manufacturing method for the semiconductor memory 1A. First, as shown in FIG. 4, the copper thin film 60A is provided on the top surface 10b of the substrate 10. The copper thin film 60A is formed by sputtering in a region exposed from an opening Mo of a mask M.

Next, as shown in FIG. 5, the controller 20 is adhesively bonded onto the copper thin film 60A via the DAF 51. The controller 20 is adhesively bonded onto the copper thin film 60A via the DAF 51.

Subsequently, the memory device 30A is adhesively bonded onto the top surface 10b of the substrate 10 via the DAF 52, and the memory device 30B is adhesively bonded onto the top surface 30b of the memory device 30A via the DAF 53.

Next, wire bonding is executed to electrically connect the controller 20, the memory devices 30, and the conductors 12 of the substrate 10 via the bonding wires 21 and 31.

Next, the cover layer 40 is placed on the top surface 10b of the substrate 10, and the cover layer 40 covers the top surface 10b of the substrate 10 and the controller 20 and the two memory devices 30 exposed onto the top surface 10b. A packaged state of the controller 20 and the two memory devices 30 in the substrate 10 and the cover layer 40 is obtained. In addition, the external electrodes 70 are provided on the bottom surface 10b of the substrate 10, thereby manufacturing the semiconductor memory 1A as shown in FIG. 1.

As described so far, in the present embodiment, the copper thin film 60A (referred to more generally as a shielding layer) lies between the top surface 10b of the substrate 10 and at least part of the bottom surface 20a of the controller 20. With such a configuration, it is possible, for example, for the copper thin film 60A to inhibit alpha radiation emitted from the substrate 10 from traveling to the controller 20 and to eventually inhibit occurrence of a data error in the RAM in the controller 20 due to the alpha radiation.

Furthermore, in the present embodiment, the thickness of the copper thin film 60A is equal to or greater than 23 [μm]. With such a configuration, it is possible, for example, for the copper thin film 60A to substantially shield the alpha radiation emitted from a typical organic substrate.

Moreover, in the present embodiment, the copper thin film 60A is provided on the top surface 10b of the substrate 10, and the controller 20 is mounted on the top surface 10b so that at least part of the controller 20 overlaps the copper thin film 60A. According to such a manufacturing method, it is possible, for example, to more easily or more reliably fabricate a structure in which the copper thin film 60A inhibits or shields the alpha radiation emitted from the substrate 10 from flying to the controller 20 using known manufacturing facilities and known manufacturing methods established for the manufacturing of semiconductor memory devices.

### Second Embodiment

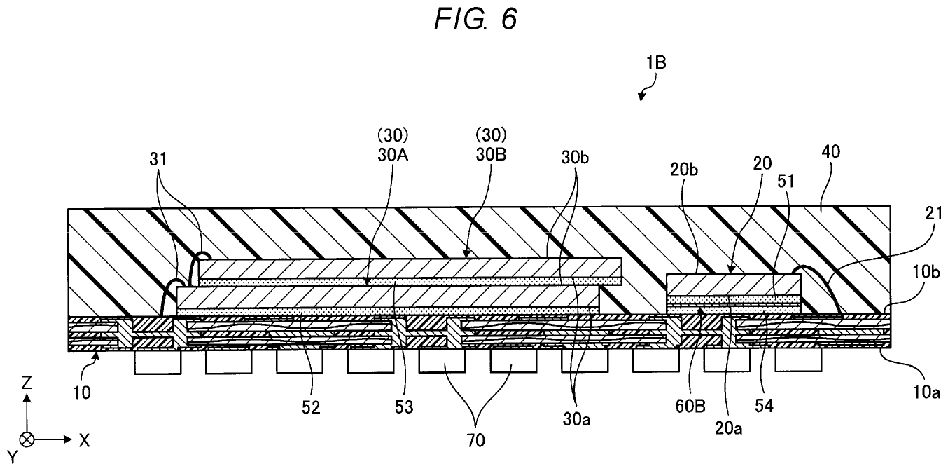

FIG. 6 is a cross-section of a semiconductor memory 1B taken in the XZ plane and viewed along the Y direction. In the second embodiment, similarly to the first embodiment, a copper thin film 60B is provided on the top surface 10b of the substrate 10; in other words, the copper thin film 60B is provided outside of the substrate 10. In the present embodiment, unlike the present embodiment, the copper thin film 60B is adhesively bonded onto the top surface 10b of the substrate 10 via a DAF 54. The DAF 54 lies between the top surface 10b and the copper thin film 60B and adhesively bonds the top surface 10b to the copper thin film 60B. The DAF 54 may be also referred to as “adhesive layer”. The copper thin film 60B is an example of a shielding layer.

In the second embodiment, similarly to the first embodiment, the copper thin film 60B lies between the top surface 10b of the substrate 10 and at least part of the bottom surface 20a of the controller 20. Furthermore, a thickness of the copper thin film 60B is equal to or greater than 23 [μm]. With such a configuration, it is possible, for example, for the copper thin film 60B to inhibit alpha radiation emitted from the substrate 10 from traveling to the controller 20 and substantially shield the alpha radiation emitted from the typical organic substrate. Therefore, it is possible to inhibit occurrence of a data error in the RAM in the controller 20 due to the alpha radiation.

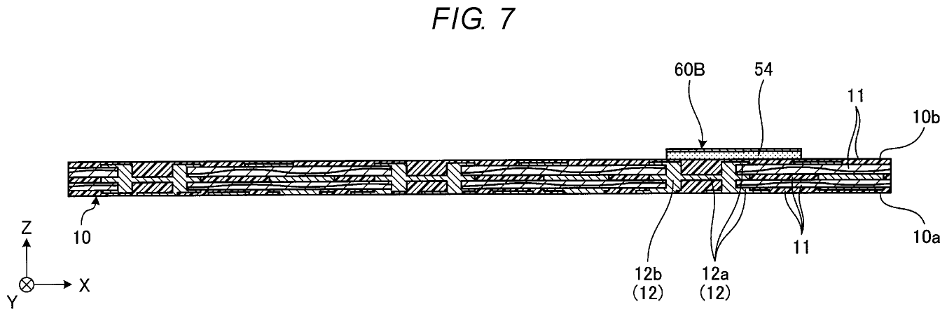

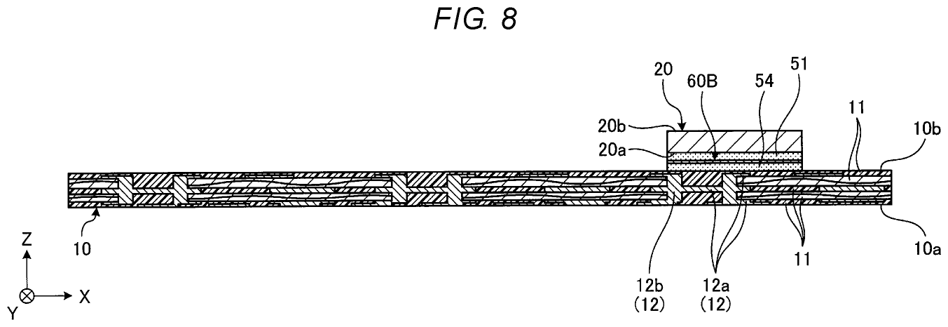

FIGS. 7 and 8 are cross-sectional views illustrating two steps of a manufacturing method for the semiconductor memory 1B. First, as shown in FIG. 7, the copper thin film 60B is provided on the top surface 10b of the substrate 10 via the DAF 54.

Next, as shown in FIG. 8, the controller 20 is adhesively bonded onto the copper thin film 60B via the DAF 51. Since subsequent processes are similar to those in the first embodiment, description is omitted.

In the present embodiment, the copper thin film 60B is adhesively bonded onto the top surface 10b of the substrate 10 via the DAF 54. According to such a manufacturing method, it is possible, for example, to more easily or more reliably fabricate a structure in which the copper thin film 60B inhibits or shields alpha radiation emitted from the substrate 10 from flying to the controller 20 using known manufacturing facilities and known manufacturing methods established for the manufacturing of semiconductor memory devices.

### Third Embodiment

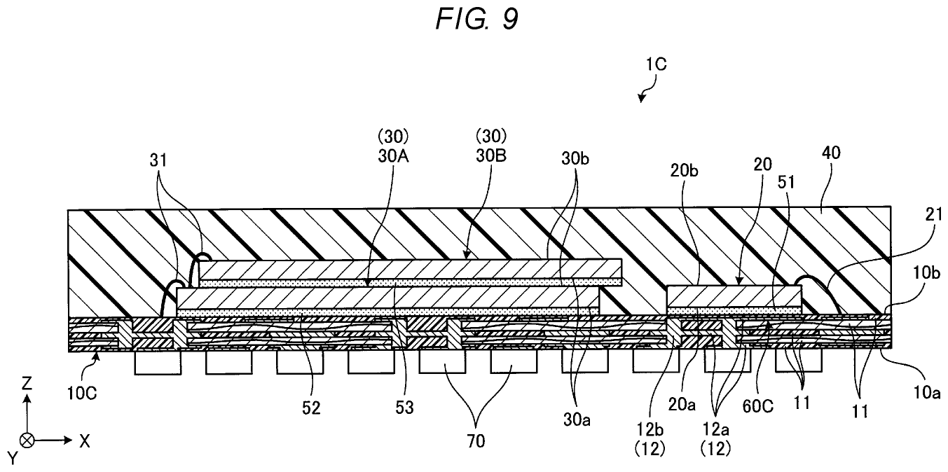

FIG. 9 is a cross-section of a semiconductor memory 1C taken in the XZ plane and viewed along the Y direction. In the third embodiment, a copper thin film 60C is provided as part of a substrate 10C. Specifically, the copper thin film 60C is located inwardly of the top surface 10b. Furthermore, the insulating layers 11 containing glass that emits alpha radiation are not present between the copper thin film 60C and the top surface 10b. The insulating layers 11 emitting the alpha radiation are located below the copper thin film 60C towards the bottom surface 10a. The substrate 10C incorporating such a copper thin film 60C can be fabricated more easily or more reliably using known manufacturing facilities and manufacturing methods established for the manufacturing of substrates. The top surface 10b is an example of a first surface, the bottom surface 10a is an example of a second surface, and the insulating layers 11 are an example a first layer.

The controller 20 is mounted on the top surface 10b of the substrate 10C. The controller 20 is adhesively bonded onto the top surface 10b via, for example, the DAF 51.

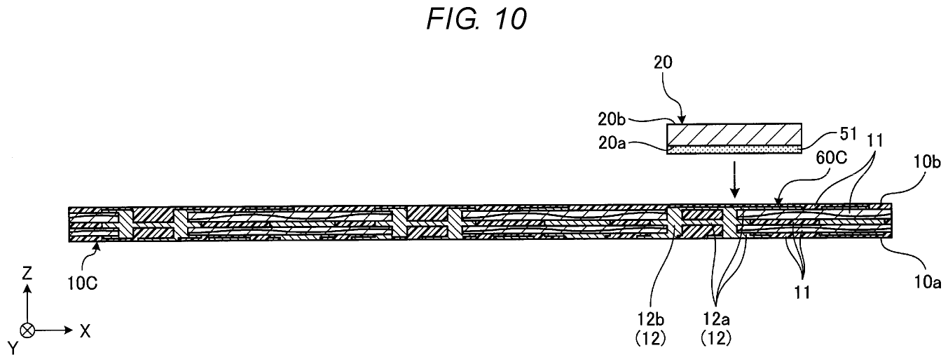

FIG. 10 is a cross-sectional view illustration one step of a manufacturing method for the semiconductor memory 1C. As shown in FIG. 10, the controller 20 is adhesively bonded onto the top surface 10b of the substrate 10C in which the copper thin film 60C is provided, via the DAF 51. At this time, the controller 20 is located so that the controller 20 overlaps the copper thin film 60A on the top surface 10b in the Z direction. Since subsequent processes are similar to those in the first embodiment, description is omitted.

In the present embodiment, the copper thin film 60C is located between the top surface 10b and the insulating layers 11 in the substrate 10, and the controller 20 is mounted on the top surface 10b at a position at which the controller 20 overlaps the copper thin film 60C in the Z direction. That is, in the present embodiment, similarly to the preceding embodiments, the copper thin film 60C lies between the insulating layers 11 and at least part of the bottom surface 20a of the controller 20. Furthermore, a thickness of the copper thin film 60C is equal to or greater than 23 [μm]. With such a configuration, it is possible, for example, for the copper thin film 60C to inhibit alpha radiation emitted from the insulating layers 11 from traveling to the controller 20 and substantially shield the alpha radiation emitted from the typical organic substrate. Therefore, it is possible to inhibit occurrence of a data error in the RAM in the controller 20 due to the alpha radiation.

Moreover, in the present embodiment, the copper thin film 60C is provided in the substrate 10C in the process of manufacturing the substrate 10C. The copper thin film 60C can be fabricated in processes for manufacturing the substrate 10C that are similar to the processes for forming the conductors 12. Therefore, according to the present embodiment, it is possible, for example, to more easily or more reliably fabricate a structure in which the copper thin film 60C inhibits or shields the alpha radiation emitted from the substrate 10C from traveling to the controller 20 using known manufacturing facilities and known manufacturing methods established for the manufacturing of substrates and semiconductor memory devices. It is noted that a thickness of the interconnection patterns 12a in the Z direction is smaller than the thickness of the copper thin film 60C. Alternatively, the thickness of the interconnection patterns 12a in the Z direction may be equal to the thickness of the copper thin film 60C.

### Fourth Embodiment

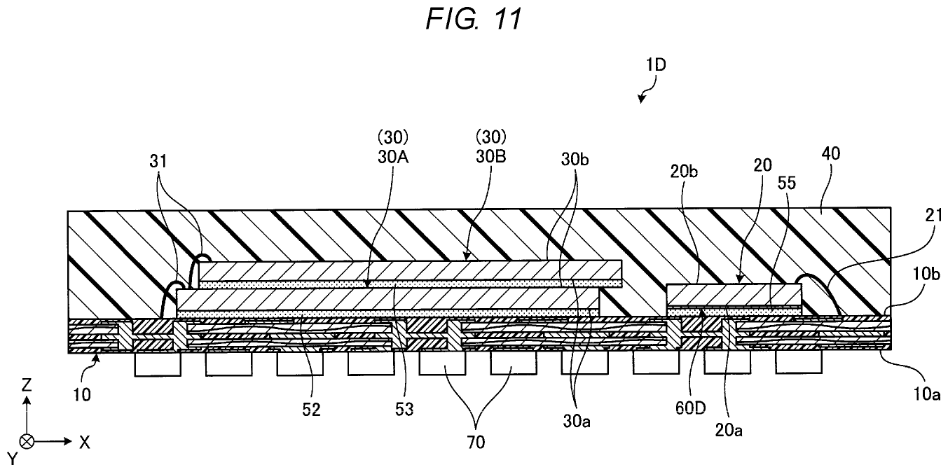

FIG. 11 is a cross-section of a semiconductor memory 1D taken in the XZ plane and viewed along the Y direction. In the fourth embodiment, a copper thin film 60D is provided on the bottom surface 20a of the controller 20; in other words, the copper thin film 60D is external to the substrate 10. The controller 20, on which the copper thin film 60D is provided, is mounted on the top surface 10b of the substrate 10 via a DAF 55 so that the bottom surface 20a faces the top surface 10b of the substrate 10. The bottom surface 20a is an example of a third surface.

In the present embodiment, similarly to the preceding embodiments, the copper thin film 60D lies between the top surface 10b of the substrate 10 and at least part of the bottom surface 20a of the controller 20. Furthermore, a thickness of the copper thin film 60D is equal to or greater than 23 [μm]. With such a configuration, it is possible, for example, for the copper thin film 60D to inhibit alpha radiation emitted from the substrate 10 from traveling to the controller 20 and substantially shield the alpha radiation emitted from the typical organic substrate.

The copper thin film 60D and the DAF 55 are provided on a wafer (not shown) before cutting the controllers 20 by dicing. Specifically, for example, after a bottom surface of the wafer is polished, the copper thin film 60D is provided by, for example, chemical vapor deposition. Next, the DAF 55 is provided on the copper thin film 60D. The copper thin film 60D and the DAF 55 are provided on the bottom surface 20a of each controller 20 by cutting the wafer to separate the plurality of controllers 20 by dicing.

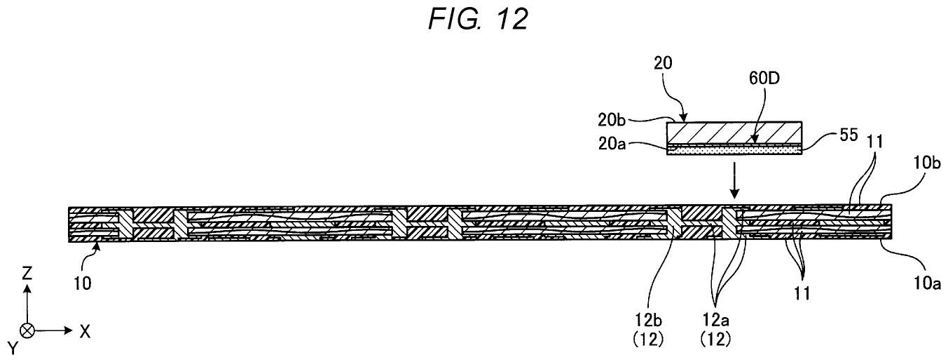

FIG. 12 is a cross-sectional view illustrating one step of a manufacturing method for the semiconductor memory 1D. As shown in FIG. 12, the controller 20 having the bottom surface 20a, on which the copper thin film 60D and the DAF 55 are provided, is adhesively bonded onto the top surface 10b of the substrate 10 via the DAF 55. Since subsequent processes are similar to those in the first embodiment, description is omitted.

In the present embodiment, the controller 20 having the bottom surface 20a on which the copper thin film 60D is provided is mounted on the top surface 10b of the substrate 10 so that the copper thin film 60D faces the top surface 10b. According to such a manufacturing method, it is possible, for example, to more easily or more reliably fabricate a structure in which the copper thin film 60D inhibits or shields alpha radiation emitted from the substrate 10 from traveling to the controller using known manufacturing facilities and known manufacturing methods established for the manufacturing of semiconductor memory devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. Furthermore, each embodiment may be implemented by partially interchanging the configuration and shapes. Moreover, the embodiments and the modifications may be implemented while specifications such as each configuration and each shape (a structure, a type, a direction, a form, a magnitude, a length, a width, a thickness, a height, the number, a disposition, a position, a material, and the like) are changed as appropriate.

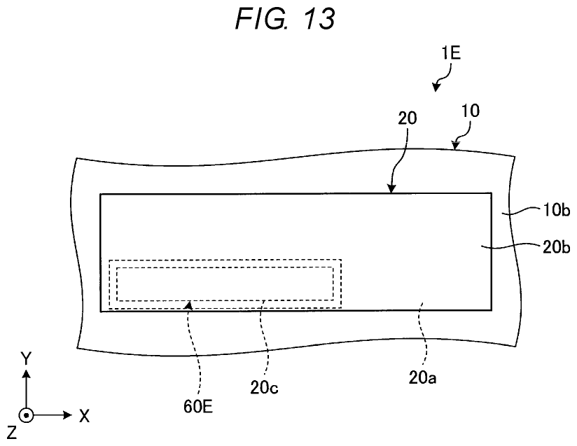

For example, a material of the shielding layer is not limited to copper. Furthermore, as shown in FIG. 13, a copper thin film 60E of a semiconductor memory 1E does not need to span or overlap the entire bottom surface 20a of the controller 20 in the Z direction but may span or overlap part of the bottom surface 20a of the controller 20 in the Z direction. Specifically, in an example of FIG. 13, the copper thin film 60E overlaps a random access memory region 20c in which the RAM such as the SRAM is provided, in other words, in which the RAM is disposed at a higher density than those of other regions in the controller 20, in the Z direction. In this example, in a plan view of FIG. 13, an outer periphery of the copper thin film 60E surrounds an outer periphery of the random access memory region 20c. In this case, the copper thin film 60E can be often made narrow and time and labor of manufacturing and a manufacturing cost, for example, can be often saved, compared with a case of providing the copper thin film 60E to correspond to an entire bottom surface 20a of the controller 20. The configuration such that the copper thin film 60E overlaps part of the controller 20 such as the random access memory region 20c in the Z direction as described above is also applicable to the configurations of the first to fourth embodiments.

What is claimed is:

1. A semiconductor memory comprising:
a substrate having a first surface;
a memory device mounted on the first surface;
a controller mounted on the first surface; and
a shielding layer between the first surface and at least apart of the controller, the shielding layer having a thickness that is large enough to block most of the alpha radiation from the substrate from reaching the part of the controller.

2. The semiconductor memory according to claim 1, wherein the shielding layer is a copper thin film having a thickness greater than or equal to 23 micrometers.

3. The semiconductor memory according to claim 2, wherein the shielding layer is between the first surface and all parts of the controller.

4. The semiconductor memory according to claim 2, wherein the controller includes a random access memory region and the shielding layer is between the first surface and the random access memory region.

5. The semiconductor memory according to claim 1, further comprising an adhesive material between the controller and the first surface.

6. The semiconductor memory according to claim 5, wherein the adhesive material is between the controller and the shielding layer, and the shielding layer makes direct contact with the substrate.

7. The semiconductor memory according to claim 5, wherein the adhesive material is between the controller and the shielding layer and between the shielding layer and the substrate.

8. A semiconductor memory comprising:
a substrate having a first surface;
a memory device mounted on the first surface; and
a controller mounted on the first surface, wherein
the substrate includes a shielding layer at the first surface, such that at least a part of the controller is mounted on the shielding layer, the shielding layer having a thickness that is large enough to block most of the alpha radiation from the substrate from reaching the part of the controller.

9. The semiconductor memory according to claim 8, wherein the shielding layer is a copper thin film having a thickness greater than or equal to 23 micrometers.

10. The semiconductor memory according to claim 9, wherein all parts of the controller are mounted on the shielding layer.

11. The semiconductor memory according to claim 9, wherein the controller includes a random access memory region and only the random access memory region of the controller is mounted on the shielding layer.

12. A semiconductor memory manufacturing method, comprising:
mounting a memory device on a first region of a substrate; and
mounting a controller on a second region of the substrate, as a result of which a shielding layer supports at least a part of the controller on the second region of the substrate, the shielding layer having a thickness that is large enough to block most of the alpha radiation from the substrate from reaching the part of the controller.

13. The method according to claim 12, further comprising:
forming a shielding layer on the second region of the substrate; and
forming a die attach film on the shielding layer,
wherein the controller is mounted on the shielding layer through the die attach film.

14. The method according to claim 12, further comprising:
forming a first die attach film on the second region of the substrate;
forming a shielding layer on the first die attach film; and
forming a second die attach film on the shielding layer,
wherein the controller is mounted on the shielding layer through the second die attach film.

15. The method according to claim 12, further comprising:
dicing a wafer having a plurality of controllers to form individual dies, one of dies including the controller.

16. The method according to claim 15, wherein the die including the controller further includes the shielding layer, which is attached to the controller through a die attach film, and the die is mounted on the substrate.

17. The method according to claim 12, wherein the shielding layer is a copper thin film having a thickness greater than or equal to 23 micrometers.

18. The method according to claim 17, wherein the shielding layer supports all parts of the controller.

19. The method according to claim 18, wherein the controller includes a random access memory region and the shielding layer only supports the random access memory region of the controller.
